(19) United States
(12) Patent Application Publication
(10) Pub. No.: US 2008/0212392 A1
(43) Pub. Date: Sep. 4, 2008

(54) MULTIPLE PORT MUGFET SRAM

(75) Inventor: Florian Bauer, Muenchen (DE)

Correspondence Address: SCHWEGMAN, LUNDBERG & WOESSNER / INFINEON, P.O. BOX 2938, MINNEAPOLIS, MN, 55402, US

(73) Assignee: INFINEON TECHNOLOGIES, MUNICH (DE)

(21) Appl. No.: 11/681,508

(22) Filed: Mar. 2, 2007

(51) Int. Cl. G11C 11/00; G11C 8/00

(52) U.S. Cl. 365/230.05; 365/154

(57) ABSTRACT

A circuit includes a multi gate field effect transistor based static random access memory device having a cross coupled inverter cell. A first set of multi gate field effect transistor access devices are coupled to the memory device to provide a first port. A second set of multi gate field effect transistor access devices are coupled to the memory device to provide a second port. Further ports may be provided in further embodiments.

### BACKGROUND

Development of semiconductor memory devices has been increasing at a fast pace because of major breakthroughs in materials, manufacturing processes and designs of semiconductor devices. Semiconductor device manufacturers are constantly enhancing their efforts for more advanced miniaturization, high-integration and capacity increase of the semiconductor devices. This has given an impetus to research and development for more stabilization, higher speeds and smoother operation of semiconductor devices. These results have been brought about by the device makers improving the process techniques, microminiature device techniques and circuit design techniques in the manufacture of semiconductor memory cells such as SRAM (Static Random Access Memory).

The push for ever increasing device densities is particularly strong in CMOS (complementary metal oxide semiconductor) technologies, such as the in the design and fabrication of field effect transistors (FETs). Unfortunately, increased device density in CMOS FET often results in degradation of performance and/or reliability.

Multiple port SRAM cells have been implemented in planar CMOS bulk processes. However, such bulk processes do not exhibit a desirable sub-threshold slope, and exhibit matching and noise immunity difficulties.

Dual port CMOS SRAM are capable of performing read and write operations at high speeds. In general, one unit memory cell of a single port CMOS SRAM device is composed of six transistors, that is, two access transistors, and four transistors configured as an inverting latch to perform the read and write operations sequentially. Word lines are coupled to the access transistors and data is provided or read on bit lines. In contrast, a dual port CMOS SRAM device is configured with an addition of two access transistors coupled to an additional word line, and a pair of additional bit lines so as to perform two read operations in parallel.

In a read operation, an externally received read address signal is decoded, and according to the decoding result, a word line signal for the read operation is enabled. Next, the access transistors are turned on, and the data stored at the latch is read through the bit line and the complementary bit line. Similarly, in the write operation, a write address signal is received and is decoded, and according to the decoding result, a word line signal for a write operation is enabled. The access transistors are then turned on, and the data loaded on the bit line and the complementary bit line is stored at the latch.

### BRIEF DESCRIPTION OF THE DRAWINGS

FIG. 1 is a schematic diagram of a dual-port MuGFET SRAM core cell according to an example embodiment.

FIG. 2 is a perspective diagram of a MuGFET transistor for use in a dual-port MuGFET SRAM core cell.

FIG. 3 is an example layout of the dual-port MuGFET SRAM core cell of FIG. 1.

FIG. 4 is a schematic diagram of a triple-port MuGFET SRAM core cell according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

A multiple port SRAM (static random access memory) cell is formed with MuGFETs (multi gate field effect transistors). The MuGFET based multiple port SRAM cell may have a better sub-threshold slope, improved matching and better noise immunity than provided by typical CMOS (complementary metal oxide semiconductor) bulk processes. The use of MuGFET transistors may also yield a compact memory cell with excellent leakage characteristics, as the off current flowing through access devices is significantly lower compared to common bulk CMOS devices. An example dual port circuit and layout are shown, along with an example triple port and n-port circuits.

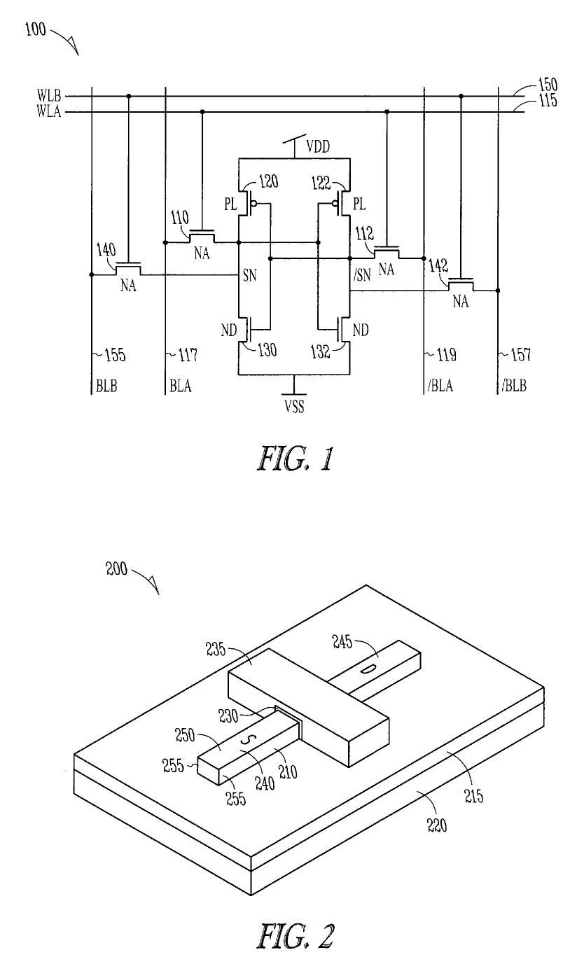

FIG. 1 is a schematic diagram of a dual-port MuGFET SRAM core cell 100 according to an example embodiment. A pair of nMOS (n-type metal oxide semiconductor) access transistors 110 and 112 have gates coupled to a first word line 115, sometimes referred to as word line A. Sources of the access transistors are coupled to a first bit line 117 (BLA) or complementary bit line 119 (/BLA). A pair of pMOS pull up transistors 120 and 122 and pair of nMOS pull down transistors 130 and 132 are coupled to form cross coupled invertors. The pull up transistors 120 and 122 are coupled to a supply voltage (VDD—voltage drain drain) and the pull down transistors 130, 132 are coupled to ground (VSS—voltage source source).

In one embodiment, the transistors are a MuGFET type of transistor, with the pull down transistors 130, 132 having one fin, or more fins for increased current capacity. The gate of the MuGFET transistor traverses at least both sides of the fin to provide a multiple gate effect on the fin, which serves as the channel of the device.

The pull up transistors may be p-type in one embodiment, with the other transistors n-type. In a further embodiment, the pull up transistors may be n-type, again with the other transistors p-type.

In one embodiment, a second set of access transistors 140, 142 are coupled between the pull up and pull down transistors in the same manner as the first set of access transistors 110 and 112. Their gates are coupled to a word line B at 150 with sources coupled to bit line B at 155 and 157.

In operation, the complementary bit lines may be charged and the various sets of access transistors may be turned on by their respective word lines. Sense amplifiers may then be used to sense the values on the bit lines to determine the value stored in the memory cell. One or both of the access transistor pairs may be turned on simultaneously or asynchronously along with the bit line charging to provide separate access to the memory cell by different devices or by different portions of a same device.

FIG. 2 illustrates a perspective view of a single fin MuGFET transistor 200 for use in the multiple-port SRAM devices. The single fin transistor 200 has a body 210, also referred to as a fin 210. The fin may be formed on an insulating surface 215 of a substrate 220 or may be formed on or supported by the substrate 220 without an insulating layer. The insulating surface may be a buried oxide or other insulating layer 210 over a silicon or other semiconductor substrate 220. A gate dielectric 230 is formed over the top and on the sides of the semiconductor fin 210. A gate electrode 235 is formed over the top and on the sides of the gate dielectric 230 and may include a metal layer. A source 240 and drain 245 regions may be formed in the semiconductor fin 210 on either side of the gate electrode, and may be laterally expanded to be significantly larger than the fin 210 under the gate electrode 235 in various embodiments.

The fin 210 has a top surface 250 and laterally opposite sidewalls 255. The semiconductor fin has a height or thickness equal to T and a width equal to W. The gate width of a single fin MuGFET transistor is equal to the sum of the gate widths of each of the three gates formed on the semiconductor body, or, T+W+T, which provides high gain. If MuGFET devices are formed on an insulator, better noise immunity may result. Formation on the insulator provides isolation between devices, and hence the better noise immunity. Better noise immunity allows the formation of multiple ports without interference with other transistors in an SRAM. Having the gate traverse two or more sides of the fin or channel results in much quicker off current than prior bulk CMOS devices.

The use of MuGFET transistors may also provide a better subthreshold slope that is steeper than in bulk CMOS devices, so the device switches off more quickly. Since the channels are formed by the use of narrow fins, improved matching of the devices may be significantly easier than in planar bulk CMOS devices, allowing better control of their current characteristics.

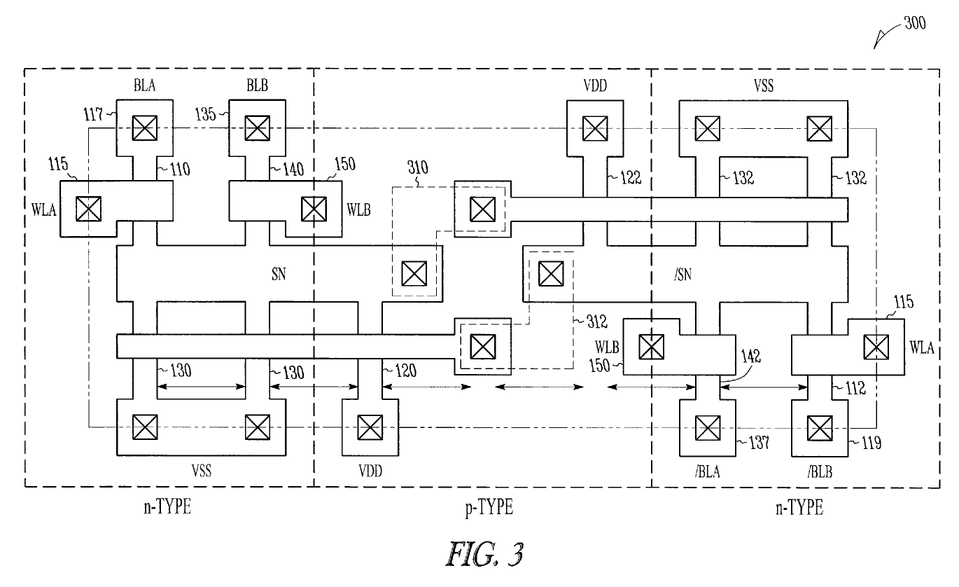

FIG. 3 is an example layout 300 of the dual-port MuGFET SRAM core cell of FIG. 1. The layout is very compact, allowing higher density SRAM cells in an array by folding the layout outward multiple times. In FIG. 3, the elements of FIG. 1 are labeled with the same numbers. The transistors are identified by the corresponding fins. The word lines and bit lines are also similarly identified along with connections to supply VDD and ground VSS. To illustrate further connections, metal paths coupling the gates to respective active areas of the pull up and pull down transistors to provide the cross coupling are also shown at 310 and 312.

Many other layouts may be used by those of skill in the art to form the dual-port MuGFET SRAM core cell of FIG. 1. Layout 300 provides discrete cell boundaries indicated by the broken or dashed lines, with a center cell boundary including only pFET transistors. This may allow different processing to be used for the different transistors to modify the current characteristics to optimize cell performance. Further layouts may be provided to optimize cell replication in an SRAM array with minimum area.

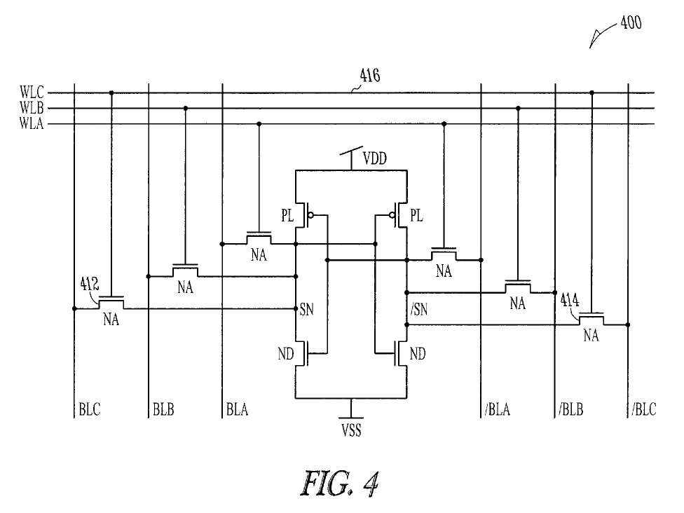

FIG. 4 is a schematic diagram of a triple-port MuGFET SRAM core cell 400 according to an example embodiment. Cell 400 is similar to cell 100 and is numbered consistently. In addition to the two sets of access devices 110, 112 and 140, 142, it further includes a third set of access device 412, 414 similarly coupled to the cross coupled inverter cell. A third word line 416 is also coupled to the third set of access devices 412, 414 to selectively turn them on to access the cross coupled inverter cell. Bit lines C 420 and C complement 422 are also coupled to the third set of access devices 412, 414 to provide the state of the cell to detection circuitry, which is not shown. Many different layouts may be used to form the triple-port MuGFET SRAM core cell 400.

Additional sets of access devices, word lines and bit lines may be provided in further embodiments to provide even further ports.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A circuit comprising:
a multi gate field effect transistor based static random access memory device having a cross coupled inverter cell;
a first set of multi gate field effect transistor access devices coupled to the memory device to provide a first port; and
a second set of multi gate field effect transistor access devices coupled to the memory device to provide a second port.

2. The circuit of claim 1 wherein the cross coupled inverter cell comprises a set of pull up multi gate field effect transistors and a pair of pull down multi gate field effect transistors.

3. The circuit of claim 2 wherein the pull down multi gate field effect transistors are multiple fin n type multi gate field effect transistors.

4. The circuit of claim 1 wherein the inverter cell is comprises four multi gate field effect transistors.

5. The circuit of claim 1 wherein the multi gate field effect transistors have fins that are approximately 20 nm in width or less.

6. A circuit comprising:
a multi gate field effect transistor based static random access memory device having a cross coupled inverter cell;
means for providing first access to the memory device; and
means for providing second access to the memory device.

7. The circuit of claim 6 wherein the means for providing first and second access comprise single fin multi gate field effect transistors.

8. The circuit of claim 6 and further comprising for means for providing third access to the memory device.

9. The circuit of claim 6 and further comprising multiple word lines, each word line coupled to one of the means for providing access.

10. The circuit of claim 9 and further comprising multiple pairs of bit lines, each pair of bit lines coupled to different means for providing access to the memory device.

11. A circuit comprising:
a cross coupled inverter memory cell for a multi gate field effect transistor based static random access memory device;
a first set of multi gate field effect transistor access devices coupled to the memory device to provide a first port;
a second set of multi gate field effect transistor access devices coupled to the memory device to provide a second port;
first and second word lines respectively coupled to the first and second sets of multi gate field effect transistor access devices; and
first and second pairs of complementary bit lines respectively coupled to the first and second sets of multi gate field effect transistor access devices.

12. The circuit of claim 11 wherein the word lines are coupled to gates of the first and second sets of multi gate field effect transistors and the bit lines are coupled to drains of the first and second sets of multi gate field effect transistors.

13. The circuit of claim 11 wherein the access devices are n-type multi gate field effect transistors.

14. The circuit of claim 11 wherein the cross coupled inverter comprises n-type pull down multi gate field effect transistors and p-type pull up multi gate field effect transistors.

15. A static random access memory circuit comprising:
multiple memory cells formed in an array, each cell comprising:
a cross coupled inverter memory cell having multi gate field effect transistors;
a first set of multi gate field effect transistor access devices coupled to the memory device to provide a first port; and
a second set of multi gate field effect transistor access devices coupled to the memory device to provide a second port.

16. The circuit of claim 15 wherein the cross coupled memory cell comprises a set of pull up multi gate field effect transistors and a pair of pull down multi gate field effect transistors.

17. The circuit of claim 16 wherein the pull down multi gate field effect transistors are multiple fin n-type multi gate field effect transistors.

18. The circuit of claim 15 wherein the inverter memory cell is formed of four multi gate field effect transistors.

19. The circuit of claim 15 wherein the multi gate field effect transistors have fins that are approximately 20 nm in width or less.

20. A circuit comprising:
a multi gate field effect transistor based static random access memory device having a cross coupled inverter cell including four multi gate field effect transistors, each having at least one fin and a gate that covers at least two sides of the fins;
a first set of multi gate field effect transistor access devices coupled to the memory device to provide a first port, each transistor having at least one fin and a gate that covers at least two sides of the fins; and
a second set of multi gate field effect transistor access devices coupled to the memory device, each transistor having at least one fin and a gate that covers at least two sides of the fins to provide a second port.

21. The circuit of claim 20 wherein the cross coupled inverter cell comprises a set of pull up multi gate field effect transistors and a pair of pull down multi gate field effect transistors.

22. The circuit of claim 21 wherein the pull down multi gate field effect transistors are multiple fin n-type multi gate field effect transistors.

23. The circuit of claim 20 wherein the fins of the multi gate field effect transistors are approximately 20 nm in width or less.

24. The circuit of claim 20 replicated in an array with a word line for each set of multi gate field effect transistor access device and complementary bit lines for each multi gate field effect transistor access device to form a static random access memory array.

25. A method of accessing a multi gate field effect transistor based memory cell, the method comprising:
charging two pairs of complementary bit lines, each coupled to separate pairs of multi gate field effect transistor access transistors; and
turning on the separate pairs of multi gate field effect transistor access transistors via separate word lines.

26. The method of claim 25 and further comprising sensing voltages on the different pairs of complementary bit lines to determine a value stored in the memory cell.

27. The method of claim 25 wherein the cross coupled inverter cell comprises set of pull up multi gate field effect transistors and a pair of pull down multi gate field effect transistors.

28. The method of claim 27 wherein the pull down multi gate field effect transistors are multiple fin n type multi gate field effect transistors.

29. The circuit of claim 25 wherein the inverter cell is formed of two multi gate field effect p-type pull-up transistors and two multi gate field effect n-type pull-down transistors.
